(19) United States
(12) Patent Application Publication
(10) Pub. No.: US 2022/0067987 A1
(43) Pub. Date: Mar. 3, 2022

(54) MAGNETIC RESONANCE IMAGING RECONSTRUCTION USING MACHINE LEARNING FOR MULTI-CONTRAST ACQUISITIONS

(71) Applicant: Siemens Healthcare GmbH, Erlangen (DE)

(72) Inventor: Marcel Dominik Nickel, Herzogenaurach (DE)

(73) Assignee: Siemens Healthcare GmbH, Erlangen (DE)

(21) Appl. No.: 17/411,527

(22) Filed: Aug. 25, 2021

(30) Foreign Application Priority Data
Aug. 26, 2020 (DE) 102020210776.9

(51) Int. Cl. G06T 11/00; G01R 33/56; G01R 33/54

(52) U.S. Cl. CPC G06T 11/006; G01R 33/5608; G06T 2210/41; G06T 2211/424; G01R 33/546

(57) ABSTRACT

The disclosure relates to MRI reconstruction of a sequence of MRI images. The MRI images are associated with different contrasts. The MRI images are based on multiple MRI measurement datasets that are acquired at different time offsets with respect to at least one excitation pulse and/or with respect to at least one refocusing pulse.

### CROSS-REFERENCE TO RELATED APPLICATIONS

The present application claims the benefit of the filing date of Germany patent application no. DE 10 2020 210 776.9, filed on August 26, 2020, the contents of which are incorporated herein by reference in their entirety.

### TECHNICAL FIELD

The disclosure relates to magnetic resonance imaging (MRI) and, in particular, to machine-learned (ML) algorithms used for MRI reconstruction.

### BACKGROUND

Acquisition of MRI data can require significant time. To accelerate the data acquisition, it is known to undersample k-space. Missing data can be reconstructed (MRI reconstruction).

Various techniques for implementing MRI reconstruction are known. One technique is referred to as compressed sensing. See, e.g., Lustig, Michael, David Donoho, and John M. Pauly. “Sparse MRI: The application of compressed sensing for rapid MR imaging.” Magnetic Resonance in Medicine: An Official Journal of the International Society for Magnetic Resonance in Medicine 58.6 (2007): 1182-1195; also see Lustig, Michael, et al. “Compressed sensing MRI.” IEEE signal processing magazine 25.2 (2008): 72-82.

Often, such techniques rely on representation of MRI images in a wavelet basis. As described in id., page 13, section “Image Reconstruction”, an optimization problem—typically defined in an [symbol] -norm—can be defined. Data consistency can be enforced by a data-consistency operation ensuring that the reconstructed image is described well by the underlying k-space data sparsely sampled. The data-consistency operation is also sometimes referred to as data-fidelity operation or forward-sampling operator. In addition to the data-consistency operation, oftentimes, a regularization operation is considered. The regularization operation is conventionally based on a non-linear [symbol] -norm. A classic formulation of the regularization operation is based on sparsity of the MRI image in a transform domain such as a wavelet domain in combination with pseudo-random sampling that can introduce aliasing artifacts that are incoherent in the respective transform domain. Another example would be a Fourier domain, in particular for acquisitions of a dynamically moving target. Another example would be total variation (TV) used in connection with non-Cartesian k-space trajectories such as radial and spiral trajectories.

Based on the data-consistency operation and the regularization operation, an iterative optimization can be implemented. The iterative optimization can include multiple iterations, each iteration including the calculation of the data-consistency operation and the regularization operation in an alternating fashion.

Recently, the regularization operation has been implemented by means of deep neural networks. Here, different iterations of the optimization are implemented by different layers of the deep neural network. See Hammernik, Kerstin, et al. “Learning a variational network for reconstruction of accelerated MRI data.” Magnetic resonance in medicine 79.6 (2018): 3055-3071, as well as Knoll, Florian, et al. “Deep learning methods for parallel magnetic resonance image reconstruction.” arXiv preprint arXiv:1904.01112 (2019). Such techniques are based on the finding that wavelet compositions can be expressed as a subset of trainable convolutions of a deep neural network such as a convolutional neural network and that soft-thresholding can be used as an activation function in the deep neural network.

It is known to acquire a sequence of MRI measurement datasets at multiple time offsets with respect to at least one excitation pulse and/or with respect to at least one refocusing pulse. Thereby, the contrast of the pixels or voxels of the MRI image is reconstructed from the MRI measurement datasets will vary. It is often said that the MRI images exhibit different contrasts. From such multi-contrast MRI images, it is possible to derive additional information. For example, parametric mapping would be possible. Another option would be diffusion weighted imaging (DWI).

It has been observed that MRI reconstruction can suffer from inaccuracies where multiple MRI measurement datasets having different contrasts are to be reconstructed.

### SUMMARY

Accordingly, a need exists for advanced techniques of MRI reconstruction. In particular, a need exists for techniques of MRI reconstruction that provide accurate results even for a sequence of MRI measurement datasets that have been acquired at multiple time offsets with respect to at least one excitation pulse and/or with respect to at least one refocusing pulse.

This need is met by the embodiments as described herein, including the claims.

A computer-implemented method of reconstructing a sequence of MRI images is provided. The method includes obtaining a sequence of MRI measurement datasets. The MRI measurement datasets of the sequence of MRI measurement datasets are each acquired using at least one undersampling trajectory in k-space and a receiver coil array. The sequence of MRI measurement datasets is acquired at multiple time offsets with respect to at least one excitation pulse; alternatively or additionally, the sequence of MRI measurement datasets is acquired at multiple time offsets with respect to a least one refocusing pulse. The method also includes performing an iterative optimization based on the MRI measurement datasets of the sequence of MRI measurement datasets. The iterative optimization includes, for each iteration of the multiple iterations of the iterative optimization, a regularization operation and a data-consistency operation to obtain a sequence of current MRI images. The current MRI images of the sequence are associated with different time offsets of the multiple time offsets. The data-consistency operation is based on differences between the MRI measurement datasets and synthesized MRI measurement datasets. The synthesized MRI measurement datasets are based on a k-space representation of a prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple time offsets.

A computer program or a computer-program product or a computer-readable storage medium includes program code. The program code can be loaded and executed by least one processor. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are each acquired using at least one undersampling trajectory in k-space and a receiver coil array. The sequence of MRI measurement datasets is acquired at multiple time offsets with respect to at least one excitation pulse; alternatively or additionally, the sequence of MRI measurement datasets is acquired at multiple time offsets with respect to a least one refocusing pulse. The method also includes performing an iterative optimization based on the MRI measurement datasets of the sequence of MRI measurement datasets. The iterative optimization includes, for each iteration of the multiple iterations of the iterative optimization, a regularization operation and a data-consistency operation to obtain a sequence of current MRI images. The current MRI images of the sequence are associated with different time offsets of the multiple time offsets. The data-consistency operation is based on differences between the MRI measurement datasets and synthesized MRI measurement datasets. The synthesized MRI measurement datasets are based on a k-space representation of a prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple time offsets.

A device includes at least one processor. The at least one processor can load and execute the program code. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are each acquired using at least one undersampling trajectory in k-space and a receiver coil array. The sequence of MRI measurement datasets is acquired at multiple time offsets with respect to at least one excitation pulse; alternatively or additionally, the sequence of MRI measurement datasets is acquired at multiple time offsets with respect to a least one refocusing pulse. The method also includes performing an iterative optimization based on the MRI measurement datasets of the sequence of MRI measurement datasets. The iterative optimization includes, for each iteration of the multiple iterations of the iterative optimization, a regularization operation and a data-consistency operation to obtain a sequence of current MRI images. The current MRI images of the sequence are associated with different time offsets of the multiple time offsets. The data-consistency operation is based on differences between the MRI measurement datasets and synthesized MRI measurement datasets. The synthesized MRI measurement datasets are based on a k-space representation of a prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple time offsets.

A computer-implemented method of reconstructing a sequence of MRI images is provided. The method includes obtaining a sequence of MRI measurement datasets. The MRI measurement datasets of the sequence of MRI measurement datasets are acquired using a respective undersampling trajectory in k-space and a receiver coil array. The sequence of MRI measurement datasets is acquired during a measurement time duration. During the measurement time duration, a movement of a patient occurs. The method includes performing an iterative optimization based on the MRI measurement datasets of the sequence of MRI measurement datasets. By performing the iterative optimization, a sequence of reconstructed MRI images is obtained. The iterative optimization includes, for each iteration of the multiple iterations of the iterative optimization, a regularization operation and a data-consistency operation. Thereby, a respective current MRI image is obtained. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations of the iterative optimization, a concatenation of multiple prior images obtained from a previous iteration of the multiple iterations. The multiple prior images are associated with multiple motion states of the movement of the patient, as well as with multiple points in time throughout the measurement time duration. The multiple prior images are warped from their respective motion state to a reference motion state.

A computer program or a computer-program product or a computer-readable storage medium includes program code. The program code can be loaded and executed by least one processor. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are acquired using a respective undersampling trajectory in k-space and a receiver coil array. The sequence of MRI measurement datasets is acquired during a measurement time duration. During the measurement time duration, a movement of a patient occurs. The method includes performing an iterative optimization based on the MRI measurement datasets of the sequence of MRI measurement datasets. By performing the iterative optimization, a sequence of reconstructed MRI images is obtained. The iterative optimization includes, for each iteration of the multiple iterations of the iterative optimization, a regularization operation and a data-consistency operation. Thereby, a respective current MRI image is obtained. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations of the iterative optimization, a concatenation of multiple prior images obtained from a previous iteration of the multiple iterations. The multiple prior images are associated with multiple motion states of the movement of the patient, as well as with multiple points in time throughout the measurement time duration. The multiple prior images are warped from their respective motion state to a reference motion state.

A device includes at least one processor. The at least one processor can load and execute the program code. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are acquired using a respective undersampling trajectory in k-space and a receiver coil array. The sequence of MRI measurement datasets is acquired during a measurement time duration. During the measurement time duration, a movement of a patient occurs. The method includes performing an iterative optimization based on the MRI measurement datasets of the sequence of MRI measurement datasets. By performing the iterative optimization, a sequence of reconstructed MRI images is obtained. The iterative optimization includes, for each iteration of the multiple iterations of the iterative optimization, a regularization operation and a data-consistency operation. Thereby, a respective current MRI image is obtained. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations of the iterative optimization, a concatenation of multiple prior images obtained from a previous iteration of the multiple iterations. The multiple prior images are associated with multiple motion states of the movement of the patient, as well as with multiple points in time throughout the measurement time duration. The multiple prior images are warped from their respective motion state to a reference motion state.

A computer-implemented method of reconstructing a sequence of MRI images is provided. The method includes obtaining a sequence of MRI measurement datasets. The MRI measurement datasets of the sequence of MRI measurement datasets are each acquired using an undersampling trajectory in k-space and a receiver coil array. The sequence of MRI measurement datasets is acquired during a measurement time duration during which a movement of the patient occurs. The method includes performing an iterative optimization to obtain a sequence of reconstructed MRI images based on the MRI measurement datasets. The iterative optimization includes, for each iteration of the multiple iterations of the iterative optimization, a regularization operation and a data-consistency operation to obtain a respective current MRI image. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple motion states of the movement of the patient and with multiple points in time throughout the measurement time duration. The regularization operation includes, for each iteration of the multiple iterations, a first convolution of the input in spatial domain, a second convolution of the input in time domain, and a third convolution of the input in motion state domain.

A computer program or a computer-program product or a computer-readable storage medium includes program code. The program code can be loaded and executed by least one processor. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are each acquired using an undersampling trajectory in k-space and a receiver coil array. The sequence of MRI measurement datasets is acquired during a measurement time duration during which a movement of the patient occurs. The method includes performing an iterative optimization to obtain a sequence of reconstructed MRI images based on the MRI measurement datasets. The iterative optimization includes, for each iteration of the multiple iterations of the iterative optimization, a regularization operation and a data-consistency operation to obtain a respective current MRI image. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple motion states of the movement of the patient and with multiple points in time throughout the measurement time duration. The regularization operation includes, for each iteration of the multiple iterations, a first convolution of the input in spatial domain, a second convolution of the input in time domain, and a third convolution of the input in motion state domain.

A device includes at least one processor. The at least one processor can load and execute the program code. The at least one processor, upon loading and executing the program code, performs a computer-implemented method of reconstructing a sequence of MRI images. The method includes obtaining a sequence of MRI measurement datasets. The MRI measurement datasets of the sequence of MRI measurement datasets are each acquired using an undersampling trajectory in k-space and a receiver coil array. The sequence of MRI measurement datasets is acquired during a measurement time duration during which a movement of the patient occurs. The method includes performing an iterative optimization to obtain a sequence of reconstructed MRI images based on the MRI measurement datasets. The iterative optimization includes, for each iteration of the multiple iterations of the iterative optimization, a regularization operation and a data-consistency operation to obtain a respective current MRI image. The data-consistency operation is based on differences between the MRI measurement datasets and synthesized MRI measurement datasets. The synthesized MRI measurement datasets are based on a k-space representation of the prior image of the multiple iterations, the undersampling trajectory, and a sensitivity map associated with the receiver coil array. An input to the regularization operation includes, for each iteration of the multiple iterations, a concatenation of multiple prior images obtained from a previous iteration of the multiple iterations. The multiple prior images are associated with multiple motion states of the movement of the patient and with multiple points in time throughout the measurement time duration. The regularization operation includes, for each iteration of the multiple iterations, a first convolution of the input in spatial domain, a second convolution of the input in time domain, and a third convolution of the input in motion state domain.

It is to be understood that the features mentioned above and those yet to be explained below may be used not only in the respective combinations indicated, but also in other combinations or in isolation without departing from the scope of the disclosure.

### BRIEF DESCRIPTION OF THE DRAWINGS/FIGURES

Embodiments of the present disclosure are described in detail below with reference to the accompanying drawings, to give those skilled in the art a clearer understanding of the abovementioned and other features and advantages of the present disclosure.

FIG. 1 schematically illustrates an example MRI device according to various embodiments.

FIG. 2 schematically illustrates an example device for MRI image reconstruction according to various embodiments.

FIG. 3 is a flowchart of an example method according to various embodiments.

FIG. 4 is a flowchart of an example method according to various embodiments.

FIG. 5 schematically illustrates an example MRI image according to various embodiments.

FIG. 6 illustrates an example measurement time duration during which multiple MRI measurement datasets are acquired according to various embodiments.

FIG. 7 illustrates an example measurement time duration during which multiple MRI measurement datasets are acquired according to various embodiments.

FIG. 8 illustrates multiple example time offsets of the MRI measurements of FIG. 7.

FIG. 9 is a flowchart of an example method according to various embodiments.

### DETAILED DESCRIPTION

Some embodiments of the present disclosure generally provide for a plurality of circuits or other electrical devices. References to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, embodiments of the disclosure will be described in detail with reference to the accompanying drawings. It is to be understood that the following description of embodiments is not to be taken in a limiting sense. The scope of the disclosure is not intended to be limited by the embodiments described hereinafter or by the drawings, which are taken to be illustrative.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various techniques described herein generally relate to MRI imaging. MRI data (or raw data) is acquired in k-space by sampling k-space. Parallel imaging can be applied. Here, MRI data is acquired using an array of receiver coils having a predefined spatial sensitivity. The set of MRI data (MRI measurement dataset) is sparsely sampled in k-space, i.e., MRI data is acquired below the Nyquist threshold for a given field of view. This is sometimes referred to as undersampling k-space. According to various examples, the MRI measurement datasets may be obtained using an undersampling trajectory. When acquiring MRI measurement datasets using an undersampling trajectory for certain k-space locations, raw MRI data is not sampled and the missing information is reconstructed later on. A so-called acceleration factor R is indicative of the fraction of those k-space locations along the undersampling trajectory for which no raw data samples are acquired. Larger (smaller) acceleration factors may result in a shorter (longer) scan times.

Then, MRI reconstruction is employed to reconstruct an MRI image (reconstructed MRI image) without or having reduced aliasing artifacts. The MRI reconstruction often relies on predetermined or calibrated coil sensitivity maps (CSMs) of multiple receiver coils of the RF receiver of the MRI device are used.

Various techniques rely on MRI reconstruction using ML algorithms Oftentimes, a trained ML algorithm can outperform conventional reconstructions (including iterative approaches such as Compressed Sensing) when applied to a known/trained acquisition. This also goes by the name of deep learning (DL) reconstruction and typically relies on neural networks. According to examples, the reconstruction of an MRI dataset is facilitated using a machine-learning (ML) algorithm and/or using trained functions. As a general rule, the ML algorithm employed in the various examples may include a trained neural network, e.g., a deep-learning network. A deep neural network that can be used for implementing the regularization operation is the U-net, see Ronneberger, Olaf, Philipp Fischer, and Thomas Brox. “U-net: Convolutional networks for biomedical image segmentation.” International Conference on Medical image computing and computer-assisted intervention. Springer, Cham, 2015. The U-net employs skip-connections between hidden layers and down-sampling and up-sampling of feature maps.

For example, an iterative optimization can include (i) a regularization operator—that is implemented by a trained neural network such as a Convolutional Neural Network (CNN)—for filtering of the input MRI dataset using convolutions and non-linear activations; and (ii) a data-consistency operator (sometimes referred to as forward-sampling operator or data fidelity operator) for computation of an MRI forward model to assure agreement of the reconstructed MRI dataset with the MRI measurement data.

This approach of using an iterative optimization together with a deep-neural network having layers associated with each iteration goes by the name of a variational neural network (VNN). The complete network is also called an unrolled image reconstruction network, or simply unrolled network.

Multiple iterations of (i) and (ii) iteratively refine the reconstructed MRI measurement dataset, wherein an appropriate optimization technique, for example a gradient descent optimization technique or Landweber iterations, or prima-dual method, or alternating direction method of multipliers as known in the art, may be used to optimize parameters from iteration to iteration, i.e., to minimize a goal function including the regularization operator and the data-consistency operator. Such optimization technique may define parts of the data-consistency operation. The data-consistency operation can be based on the squared [symbol] ₂-norm of the difference between measured data and synthesized data using a signal model. A gradient can be considered, in accordance with the optimization technique. In particular for decorrelated data with Gaussian noise this can be a good choice. The signal model can be SENSE-type and, in particular, may rely on predefined CSMs. The CSMs can be calculated separately.

By using the ML algorithm in the context of the iterative optimization and, more specifically, the regularization operation, an increased image quality of the respective reconstructed MRI dataset may be provided. A reduced noise amplification and reduced image artifacts can be obtained, in comparison with the conventional reconstruction techniques. The natural image appearance may be better preserved using ML algorithm, e.g., without causing significant blurring in comparison to techniques with hand-crafted regularization operators. Conventional compressed sensing techniques may be slow and may result in less natural looking images. Using the ML algorithm, faster image reconstruction may be achieved using a predefined number of iterations of the ML algorithm. The reconstruction time is usually several orders of magnitude faster than in other iterative methods. A further advantage of such deep-learning MRI reconstruction is that patient-specific tuning of the regularization operation of the iterative optimization is not required.

One or more parameters of the ML algorithm may be determined using a training based on a ground-truth MRI dataset, which may comprise reference MRI images with reduced MRI artifacts and/or noise amplification. The ground-truth MRI dataset can be used to generate synthetic undersampled MRI data and then MRI reconstruction can be used to reconstruct a synthetically undersampled. An offline end-to-end training is possible to obtain better results.

Next, details with respect to the variational network/the unrolled network implementing the iterative optimization are described.

For an unrolled network one considers N iterations. [symbol] =1 . . . N is the index counting iterations of the optimization. The number of iterations is a hyperparameter and the networks vary from iteration to iteration, possibly also in the architecture. At the beginning [symbol] , an initial guess for the image tensor I⁽⁰⁾ is assumed which has e.g. vanishing entries or which is an initial non-trained reconstruction. From there, in each iteration:

An image tensor J⁽ⁿ⁾ is determined at which the next gradient will be evaluated. For known approaches this is a linear combination of the previous image tensors I⁽ⁿ⁾, i.e. J⁽ⁿ⁾=Σᵢ₌₀ⁿ⁻¹λᵢI⁽ⁱ⁾. The coefficients may be fixed or trained. For λᵢ=cδ_{i,n-1} this is an ISTA-like iteration. Also Nesterov accelerations are used.

The previous images may be concatenated to a tensor [symbol] (n)=(I⁽⁰⁾, . . . , I⁽ⁿ⁻¹⁾) with an additional dimension running over n. Then, one can determine from Equation 1 as follows:

J⁽ⁿ⁾=K⁽ⁿ⁾⊗ [symbol] ⁿ Eqn. 1:

where the convolution kernel K⁽ⁿ⁾ treats n as a channel (i.e. has dense connections for this dimensions) and may further convolute spatial and/or other existing dimensions. All known updates are a subset of this generalization.

Also, a restriction to a limited number of previous images is possible. Further, the convolution kernel K⁽ⁿ⁾ may be considered as known (relying on conventional optimization with momentum), trained, but initialized with an initial guess based on conventional techniques or trained as the other parameters (with some random initialization scheme).

The gradient g⁽ⁿ⁾ is calculated at J⁽ⁿ⁾. Again, it is possible to stack all calculated gradients [symbol] ⁽ⁿ⁾=(g⁽¹⁾, . . . , g⁽ⁿ⁾) or consider at least more than one gradient.

A new image candidate is calculated. In the most abstract form through Equation 2 as follows:

Ĩ⁽ⁿ⁾=Q⁽ⁿ⁾⊗( [symbol] ⁽ⁿ⁾, [symbol] ⁽ⁿ⁾) Eqn. 2:

with convolution kernel Q⁽ⁿ⁾. The latter may be externally provided and the formulation also covers conventional gradient descent optimization with and without momentum.

Finally, Ĩ⁽ⁿ⁾ is passed through a deep neural network [symbol] ⁽ⁿ⁾, which serves as the regularization operation as represented in Equation 3 as:

I⁽ⁿ⁾= [symbol] ⁽ⁿ⁾(Ĩ⁽ⁿ⁾). Eqn. 3:

This is the main trained component of the reconstruction. I^{(N)} is the reconstructed MRI image.

As a general rule, various undersampling trajectories may be used. For instance, Cartesian undersampling trajectories can be used. It would also be possible to use non-Cartesian undersampling trajectories, e.g., spiral trajectories or random trajectories. Cartesian undersampling trajectories are also referred to as regular undersampling trajectories.

The amount of undersampling, e.g., missing data points to full sampling of k-space, is often referred to as acceleration factor. Firstly, for sake of simplicity, regular undersampling of k-space with acceleration factor R is assumed. A SENSE-type reconstruction can be used, see Pruessmann, Klaas P., et al. “SENSE: sensitivity encoding for fast MRI.” Magnetic Resonance in Medicine: An Official Journal of the International Society for Magnetic Resonance in Medicine 42.5 (1999): 952-962.

R pixels are aliased in the phase encoding plane (considering 2d or 3d Cartesian undersampling trajectories) and for the linear parallel imaging problem only those are correlated. Assuming N_{c} receiver channels, the SENSE reconstruction decouples and simplifies to the following problem, to be solved by an iterative optimization as shown in Equation 4:

$$I = arg {min}_{I} {‖ CI - D ‖}^{2} \qquad Eqn . 4$$

where C is an N_{c}×R dimensional complex-valued matrix, I a vector with R elements and D the aliased MRI data of an MRI data of an MRI dataset in image space with N_{c} components. Equation (4) defines the data-consistency operation. It ensures that the k-space representation of the reconstructed image equals the measured data. The data-consistency operation is thus based on the difference between the MRI measurement dataset and a synthesized MRI measurement dataset that is based on the k-space representation of a prior image of the multiple iterations, the undersampling trajectory, and the CSMs, all included in the matrix C (thus, constituting the signal model). The reconstructed image is given in Equation 5 as:

I=(C⁵⁵⁴C)⁻¹C^{†}D. Eqn. 5:

Thus, as will be appreciated from the above, the iterative optimization to obtain the reconstructed MRI image is performed based on the MRI measurement dataset that has been acquired using an undersampling trajectory of k-space and a receiver coil array. The iterative optimization includes, for each iteration the regularization operation, see equation (3) and the data-consistency operation, see equation (2), and equation (4). The regularization operation, as a general rule, can balance a trade-off between the data consistency and the prior image. The regularization operation can be based on prior knowledge on the expected properties of the MRI images. One goal of the regularization operation is to discriminate between the actual MRI image and aliasing artifacts due to the undersampling. Thus, as a general rule, the regularization operation depends on the undersampling trajectory.

According to various examples, it is possible to obtain a sequence of multiple MRI measurement datasets. Each MRI measurement dataset of the sequence can include raw data that has been acquired at the respective time offset with respect to an excitation pulse and/or with respect to a refocusing pulse. Thus, different MRI measurement datasets can exhibit different contrasts.

Generally, the techniques used for MRI reconstruction can rely on a joint regularization operation applied to multiple MRI images obtained in an iteration of the iterative optimization. That is, the regularization operation accepts multiple MRI images as an input. More specifically, the regularization operation has an input that includes a concatenation of multiple prior images obtained from a previous iteration of the multiple iterations. The concatenation can correspond to a stacking of the multiple prior images along a channel dimensions of the ML algorithm, e.g., a deep neural network, implementing the regularization operation. Such a concatenation of the multiple prior images can thus have a high dimensionality. For example, each prior image can have a 2D or 3D spatial dimension. A further dimension is added for time. Optionally, yet a further dimension is added for motion state.

As a general rule, each MRI measurement dataset of the multiple MRI measurement datasets of the sequence can fully sampled the k-space within a given field of view.

Undersampling can be employed. In particular, comparably high acceleration factors can be used, e.g., acceleration factors of the undersampling trajectory that are not smaller than 3 or 4 or even 10.

As a general rule, various MRI sequences and protocols can be used to acquire the MRI measurement datasets. Some examples are explained below in Table 1.

TABLE 1
multiple options for MRI sequences and protocols that
can benefit from the techniques described herein.

| Example | Brief description | Detailed Description |
|---|---|---|
| I | HASTE sequence | The HASTE sequence - also called single-shot |
| | | fast spin-echo - typically performs a single |
| | | excitation and then acquires the k-space data for |
| | | one MRI image. |
| | | The term ‘excitation’ and ‘shot’ are often used in |
| | | an interchangeable manner. |
| | | Acquisition of MR data after an excitation pulse |
| | | is referred to as an echo train. The MRI image is |
| | | built from multiple MRI measurement datasets |
| | | acquired at different time offsets with respect to |
| | | the excitation pulse, i.e., at different positions in |
| | | the echo train. |
| | | The benefit is the robustness to motion, but the |
| | | drawback is that the length of the echo train over |
| | | which the contrast of the magnetization changes. |
| | | In particular, species with shorter T2 decay |
| | | significantly over the echo train and appear |
| | | blurred. The length of the echo train also restricts |
| | | the achievable resolution. Furthermore, RF |
| | | pulses with less optimal slice profile and higher |
| | | readout bandwidth are used to reduce the |
| | | temporal spacing (called echo spacing) between |
| | | the acquisition of k-space samples. |
| | | It is therefore desirable to shorten the echo train, |
| | | i.e., the amount of k-space samples and |
| | | corresponding MRI measurement datasets. On |
| | | the other hand, it is possible to acquire additional |
| | | MRI measurement datasets before or after the |
| | | target MRI measurement dataset of a desired |
| | | contrast (such MRI measurement data sets before |
| | | or after the desired contrast are referred to as |
| | | auxiliary MRI measurement data sets). If the |
| | | auxiliary MRI measurement datasets are |
| | | available, they can be used to enhance the image |
| | | quality of the target MRI measurement dataset |
| | | acquired at the desired time offset with respect to |
| | | the excitation pulse, i.e., at the desired contrast. |
| | | Accordingly, the HASTE sequence uses multiple |
| | | (at least 2) concatenated echo trends that |
| | | individually sample k-space at a higher |
| | | undersampling rate and enable joint |
| | | reconstruction. |
| | | This can be done using a single shot, i.e., using a |
| | | single excitation pulse. Alternatively, it would be |
| | | possible to use more than one shot to acquire the |
| | | MRI measurement datasets, possibly with |
| | | multiple contrasts in each shot. This comes at the |
| | | challenge to align the MRI measurement data |
| | | sets, because there can be patient motion. The |
| | | trainable algorithm used for the MRI |
| | | reconstruction or, in particular, the regularization |
| | | operation, can be designed to be able to cope |
| | | with such patient motion. For example, suitable |
| | | training can be performed, e.g., data |
| | | augmentation by deformation, acquisition with |
| | | navigation signal. |
| | | It should be noted that a multi-shot acquisition |
| | | has strong similarities with Turbo Spin Echo |
| | | (TSE), also called Fast Spin Echo (FSE). The |
| | | difference is that the single acquisition covers the |
| | | complete k-space, though at a high |
| | | undersampling rate, instead of only segments of |
| | | k-space. |
| | | A HASTE sequence can be seen as a Turbo Spin |
| | | Echo sequence with interleaved highly |
| | | undersampled acquisition of segments in k-space. |
| | | An example implementation of the HASTE |
| | | sequence is described in U.S. Pat. No. 5,459,401. |
| II | Parametric mapping | There are different parametric mapping methods |
| | | that acquire MRI measurement datasets with |
| | | different contrasts and then fit a signal model to |
| | | it. For example, the fitting can be pixel-by-pixel. |
| | | One or more physical quantities can be |
| | | quantitatively determined based on the fit. |
| | | Examples are water-fat separation based on the |
| | | Dixon method, T1-mapping with variable flip |
| | | angles in a gradient echo sequence, T1-mapping |
| | | based on an inversion or saturation, T2-mapping |
| | | using a multi-echo spin-echo sequence, etc. Even |
| | | a combination of the approaches mentioned |
| | | above are conceivable. |
| | | It is possible to increase the quality of the MRI |
| | | images when performing parametric mapping, |
| | | based on the techniques described herein. For |
| | | quantitative imaging as described above, an |
| | | accuracy of the physical observable obtained |
| | | from a fitting of the signal model can be |
| | | increased. |
| | | A single shot sequence for parametric mapping is |
| | | described in Arefeen, Yamin Ishraq. Acquisition |
| | | and reconstruction techniques for improving |
| | | rapid magnetic resonance imaging with |
| | | applications in fetal imaging. Diss. |
| | | Massachusetts Institute of Technology, 2019. |
| III | DWI imaging | Also, DWI aims to reduce the echo train length, |
| | | suffering from similar drawbacks as HASTE. |
| | | There it is often performed in single-shot |
| | | acquisitions or k-space sampled segment-by- |
| | | segment. |

As will be appreciated from Table 1, there can be scenarios in which the measurement time duration over which the multiple MRI measurement datasets are acquired is a significant length. Then, it is possible that, during the time duration, patient motion is experienced. The measurement time duration during which the sequence of MRI measurement datasets is acquired can be in the order of seconds or tens of seconds or even minutes. The measurement time duration can be long enough so that the MRI measurement datasets are subject to movement of the patient. In other words, there is a potential for motion artifacts.

Hereinafter, techniques are described that facilitate providing multiple reconstructed MRI images for the sequence of MRI measurement datasets without or at least with reduced motion artifacts.

According to the techniques described herein, multiple options are available to mitigate or reduce motion artifacts. Some examples are summarized in Table 2 below.

TABLE 2
multiple options for mitigating motion artifacts. By using such options
as illustrated in TAB. 1, the image quality can be increased.

| Option | Brief description | Details |
|---|---|---|
| I | Image warping prior to | According to one option, it is possible that the |
| | regularization operation | input to the regularization operation includes, for |
| | | each iteration of the multiple iterations, a |
| | | concatenation of multiple prior images obtained |
| | | from a previous iteration of the multiple |
| | | iterations. These multiple prior images are |
| | | associated with multiple motion states of the |
| | | movement of the patient during the measurement |
| | | time duration, as well as with multiple points in |
| | | time throughout the measurement time duration. |
| | | The multiple prior images are warped from the |
| | | respective motion states to a reference motion |
| | | state. |
| | | This corresponds to aligning the multiple prior |
| | | images with respect to each other. It is expected |
| | | that for aligned prior images the regularization |
| | | operation works better between different points in |
| | | time and motion states. |
| | | Option I can have the advantage - e.g., if |
| | | compared to option II described below - that it |
| | | may not be required to train the ML algorithm |
| | | used for the regularization operation to |
| | | compensate for different motion states and/or |
| | | points in time associated with the multiple MRI |
| | | measurement datasets of the sequence. Then, the |
| | | ML algorithm - e.g., a deep neural network - can |
| | | be less focused on learning motion effects, and |
| | | rather can focus on similarities of contrast |
| | | behavior. |
| II | Image warping | According to a further option, it is possible that |
| | incorporated into | the regularization operation - e.g., implemented |
| | regularization | by a ML algorithm such as a deep neural network - |
| | | has been trained to compensate motion artifacts. |
| | | According to some options, it would be possible |
| | | that the input to the regularization operation |
| | | includes, for each iteration of the multiple |
| | | iterations, a concatenation of multiple prior |
| | | images obtained from a previous iteration of the |
| | | multiple iterations. The multiple prior images are |
| | | again associated with multiple motion states of |
| | | the movement of the patient and with multiple |
| | | points in time throughout the measurement time |
| | | duration, as in option I. |
| | | Then, the regularization operation can include, for |
| | | each iteration of the multiple iterations, a first |
| | | convolution of the input in spatial domain, a |
| | | second convolution of the input in time domain, |
| | | and a third convolution of the input in motion |
| | | states domain. |
| | | Thus, separate spatial, time and motion-state |
| | | convolutions are executed. This helps in an |
| | | increased flexibility in the perspective choice of |
| | | time resolution, motion states, etc. These spatial, |
| | | time and motion-state convolutions can also be |
| | | trained separately. Thus, the training parameters |
| | | can be reduced, therefore, a more generalizable |
| | | unrolled network may be obtained for the |
| | | regularization operation. |

Next, details with respect to the option I of Table 2 will be explained. It is possible that the multiple prior images are warped from the respective motion states to the reference motion state using warping operators. The warping operators can be derived from motion fields. These warping operators transform an image from a first motion state to a second motion state. It is possible that the warping operators are not updated for every iteration of the iterative optimization, e.g., to increase performance and stability. The warping operators can specify a rigid transformation, e.g., including rotations, translations, and/or reflections. The warping operators can also include non-rigid contributions, e.g., skew or distort the MRI measurement datasets.

For example, scenarios are conceivable where, both, time resolution, as well as motion-state resolution is provided. For instance, it would be possible to capture MRI datasets every couple of seconds—e.g., every 10 seconds—over a measurement time duration in the order of minutes—e.g., 5 to 10 minutes. Then, it is conceivable that the motion pattern underlying the motion states that are observed varies over the course of the measurement time duration. It is possible that such changes in the motion pattern are not considered, e.g., that the warping operators remain fixed as a function of time within the measurement time duration.

The warping to an aligned state (reference motion state) in temporal and motion-state dimension is denoted as [symbol] and its inverse as W⁻¹ (warping operators). W⁻¹ corresponds to unwarping.

It is possible, but not mandatory, that the warping operators change over the course of the iterative optimization. In other words, it would be possible that W⁽ⁿ⁾ (as well as W⁽ⁿ⁾⁻¹) are determined from Ĩ⁽ⁿ⁾, I⁽ⁿ⁻¹) or from W⁽ⁿ⁾⁻¹ (as well as W⁽ⁿ⁻¹⁾⁻¹). More generally speaking, it would be possible that the warping operators are adjusted throughout the iterative optimization. Such an adjustment may depend on one or more prior images of one or more previous iterations of the iterative optimization and/or the current image. A respective registration can be performed between pairs of the one or more prior images and/or the current image. Alternatively or additionally, such adjustment may depend on one or more prior warping operators of one or more prior iterations of the iterative optimization.

Such a change of the warping operators over the course of the iterative optimization corresponds to a joint optimization of the warping operators and the MRI images. Thereby, both the quality of the current MRI images over the course of the iterations can be increased, as well as the quality of the current warping operators over the course of iterations.

Such techniques are based on the finding that the current images of early iterations of the iterative optimization can vary from implementation to implementation. In particular, an initial assumption of the current image for a first iteration of the iterative optimization can vary from implementation to implementation. For instance, all pixel values may be set to “0” for the initial current MRI image of the iterative optimization. As a general rule, a highly spatially-resolved registration between multiple MRI images may not be possible for early iterations of the iterative optimization, due to the limited accuracy. A registration and a limited spatial resolution may nonetheless be possible. This can be exploited in order to iteratively adjust the warping operators.

For instance, a spatial resolution of the warping operators may be increased as a function of the iterations. This can be aligned with the assumption that the reconstruction of the MRI images will become more and more accurate over the course of iterations.

Based on the warping operators, it is possible to generalize Eqn. (3) as Equation 6 as follows:

I⁽ⁿ⁾= [symbol] ⁽ⁿ⁾⁻¹( [symbol] ⁽ⁿ⁾( [symbol] ⁽ⁿ⁾(Ĩ⁽ⁿ⁾))) Eqn. 6

[symbol] ⁽ⁿ⁾ as well as [symbol] ⁽ⁿ⁾⁻¹—defining an un-warping of the current MRI images to their respective motion states—may be determined through a conventional algorithm—e.g., image registration based on preliminary MRI images—or a neural network. In the latter case, the further unrolled network may be understood as a complete network and trained end-to-end along with the neural network that yields the warping operators. Examples of neural networks that can be used to determine the warping operators are given by: de Vos, Bob D., et al. “A deep learning framework for unsupervised affine and deformable image registration.” Medical image analysis 52 (2019): 128-143; and Krebs, Julian, et al. “Unsupervised probabilistic deformation modeling for robust diffeomorphic registration.” Deep Learning in Medical Image Analysis and Multimodal Learning for Clinical Decision Support. Springer, Cham, 2018. 101-109; and Balakrishnan, Guha, et al. “An unsupervised learning model for deformable medical image registration.” Proceedings of the IEEE conference on computer vision and pattern recognition. 2018.

The warping operators can be determined or initialized based on a preliminary, further MRI reconstruction. Thus, the further MRI reconstruction can yield a sequence of preliminary MRI images based on the MRI measurement data sets of the sequence of MRI measurement data sets. It is then possible to determine the warping operators based on the sequence of preliminary MRI images. For example, an image registration between each one of the preliminary MRI images and a selected one of the preliminary MRI images can be performed. It would be possible that the warping operators are determined using a further neural network. The further neural network can implement the image registration. Also, conventional techniques for the image registration are possible.

For example, a conventional MRI reconstruction may be used to obtain the sequence of preliminary MRI images. It would be possible to rely on a compressed sensing MRI reconstruction.

The further image reconstruction can be based on low-resolution representations of the MRI measurement datasets. For example, it would be possible to discard certain raw data samples or discard, an image domain, pixels or voxels. This makes it faster and less computationally expensive. At the same time, an accuracy achievable when determining the warping operators can be still sufficient.

The inverse warping operators [symbol] ⁻¹ could be determined based on the forward warping operators [symbol] . Such techniques are generally known, e.g., from Chen, Mingli, et al. “A simple fixed-point approach to invert a deformation field a.” Medical physics 35.1 (2008): 81-88.

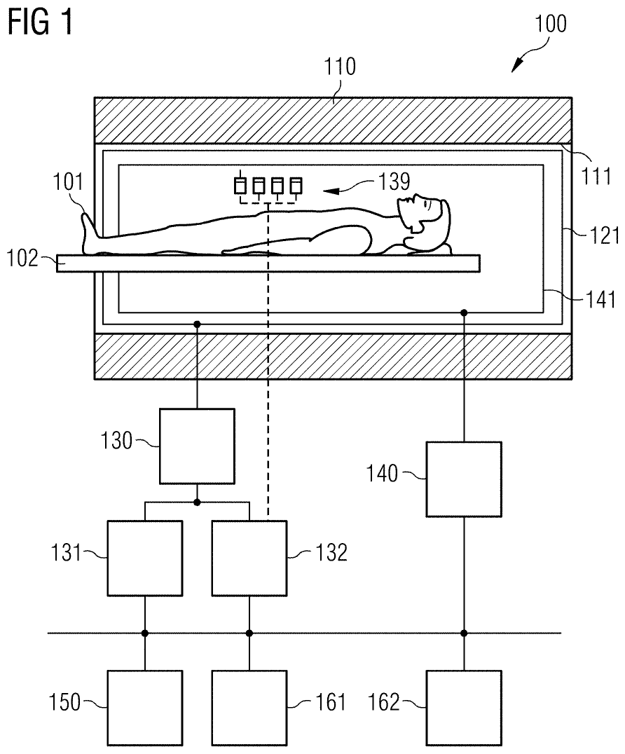

FIG. 1 depicts embodiments with respect to an MRI device 100. The MRI device 100 includes a magnet 110, which defines a bore 111. The magnet 110 may provide a DC magnetic field of one to six Tesla along its longitudinal axis. The DC magnetic field may align the magnetization of the patient 101 along the longitudinal axis. The patient 101 may be moved into the bore by means of a movable table 102.

The MRI device 100 also includes a gradient system 140 for creating spatially-varying magnetic gradient fields (gradients) used for spatially encoding MRI data. Typically, the gradient system 140 includes at least three gradient coils 141 that are arranged orthogonal to each other and may be controlled individually. By applying gradient pulses to the gradient coils 141, it is possible to apply gradients along certain directions. The gradients may be used for slice selection (slice-selection gradients), frequency encoding (readout gradients), and phase encoding along one or more phase-encoding directions (phase-encoding gradients). Hereinafter, the slice-selection direction will be defined as being aligned along the Z-axis; the readout direction will be defined as being aligned with the X-axis; and a first phase-encoding direction as being aligned with the Y-axis. A second phase-encoding direction may be aligned with the Z-axis. The directions along which the various gradients are applied are not necessarily in parallel with the axes defined by the coils 141. Rather, it is possible that these directions are defined by a certain k-space trajectory, which, in turn, may be defined by certain requirements of the respective MRI sequence and/or based on anatomic properties of the patient 101.

For preparation and/or excitation of the magnetization polarized/aligned with the DC magnetic field, RF pulses may be applied. For this, an RF coil assembly 121 is provided which is capable of applying an RF pulse such as an inversion pulse or an excitation pulse or a refocusing pulse. While the inversion pulse generally inverts the direction of the longitudinal magnetization, excitation pulses may create transversal magnetization.

For creating such RF pulses, a RF transmitter 131 is connected via a RF switch 130 with the coil assembly 121. Via a RF receiver 132, it is possible to detect signals of the magnetization relaxing back into the relaxation position aligned with the DC magnetic field. In particular, it is possible to detect echoes; echoes may be formed by applying one or more RF pulses (spin echo) and/or by applying one or more gradients (gradient echo). The magnetization may inductively coupled with the coil assembly 121 for this purpose. Thereby, raw MRI data in k-space is acquired; according to various examples, the associated MRI measurement datasets including the MRI data may be post-processed in order to obtain images. Such post-processing may include a Fourier Transform from k-space to image space. Such post-processing may also include MRI reconstruction configured to avoid motion artifacts.

Generally, it would be possible to use separate coil assemblies for applying RF pulses on the one hand side and for acquiring MRI data on the other hand side (not shown in FIG. 1). For example, for applying RF pulses a comparably large body coil 121 may be used; while for acquiring MRI data a surface coil assembly including an array of comparably small coils could be used. For example, the surface coil assembly could include 32 individual RF coils arranged as receiver coil array 139 and thereby facilitate spatially-offset coil sensitivities. Respective CMSs are defined.

The MRI device 100 further includes a human machine interface 150, e.g., a screen, a keyboard, a mouse, etc. By means of the human machine interface 150, a user input may be detected and output to the user may be implemented. For example, by means of the human machine interface 150, it is possible to set certain configuration parameters for the MRI sequences to be applied.

The MRI device 100 further includes a processing unit (e.g. a processor or processor circuitry) 161. The processor 161 may include a GPU and/or a CPU. The processor 161 may implement various control functionality with respect to the operation of the MRI device 100, e.g., based on program code (e.g. executable instructions) loaded from a memory 162. For example, the processor 161 could implement a sequence control for time-synchronized operation of the gradient system 140, the RF transmitter 131, and the RF receiver 132. The processor 161 may also be configured to implement an MRI reconstruction, i.e., implement post-processing for MRI reconstruction of MRI images based on MRI measurement datasets.

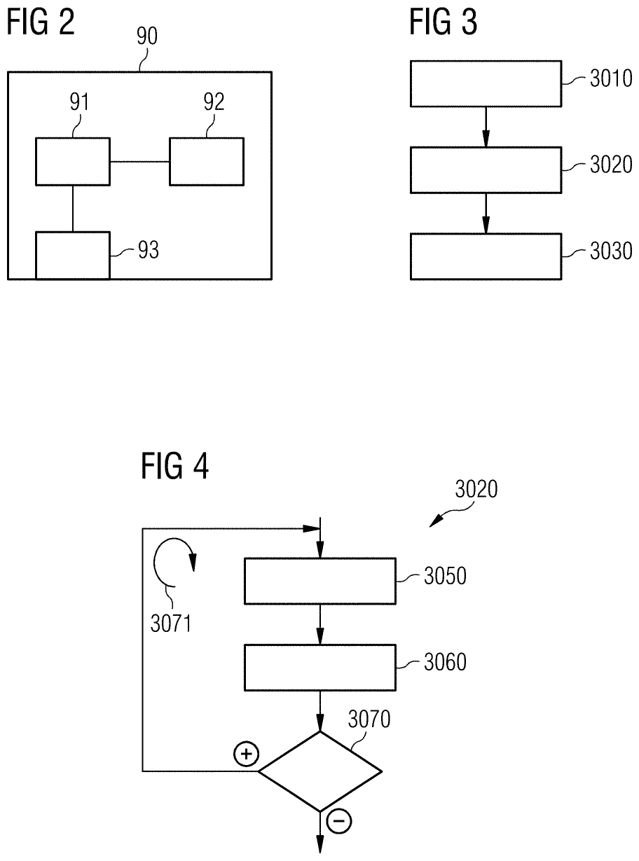

It is not required in all scenarios that processor 161 implements post-processing for reconstruction of the MRI images. In other examples, it would be possible that respective functionalities implemented by a separate device, such as the one as illustrated in FIG. 2.

FIG. 2 schematically illustrates a device 90 according to various examples. The device 90 includes a processing unit/processor 91 and a memory 92. The processor 91 can obtain an MRI measurement dataset via an interface 93, e.g., from a hospital database, a computer-readable storage medium (e.g. a non-transitory computer-readable storage medium), or directly from an MRI device 100 as discussed in connection with FIG. 1. Upon loading program code from the memory 92, the processor 91 can post-process the MRI measurement dataset to reconstruct an MRI image. Details with respect to such processing are illustrated in connection with FIG. 3.

FIG. 3 is a flowchart of a method according to various examples. For illustration, the method of FIG. 3 could be executed by the processor 161 of the MRI device 100, upon loading program code from the memory 162. The method of FIG. 3 may be executed by the processor 91 of the device 90, upon loading program code from the memory 92.

At box 3010, a sequence of MRI measurement dataset is obtained. The MRI measurement datasets have been acquired using an undersampling trajectory of k-space and a receiver coil array (cf. FIG. 1, MRI device 100, receiver coil array 139). The MRI measurement datasets have different time offsets with respect to one or more RF excitation pulses and/or RF refocusing pulses (i.e., the adjacent RF pulses governing the observed signal); i.e., the MRI measurement datasets have different contrasts.

As a general rule, it would be possible to use only a single excitation, i.e., acquire the multiple MRI measurement datasets in a single shot. It would also be possible to use multiple excitation pulses; for example, it would be possible to use a comparably limited amount of excitation pulses, e.g., less than 6 excitation pulses. It would be possible that different MRI measurement datasets of the sequence of MRI measurement datasets are acquired using different undersampling trajectories. Using only a few or a single excitation can be applicable, in particular, to a HASTE sequence, as explained above in TAB. 1, example I.

As will be explained next, it is generally possible to very one or more acquisition parameters for the acquisition of the multiple MRI measurement datasets. By such variations of the acquisition parameters for the multiple MRI measurement datasets of the sequence of MRI measurement data sets, complementary information can be obtained so that the overall image quality of one or more reconstructed MRI images increases. This can be, in particular, helpful for single shot acquisitions or acquisitions using only a few RF excitation pulses.

For example, it would be possible to use multiple undersampling trajectories that have the same acceleration factor, but are configured differently, e.g., with respect to the particular samples taken in k-space. For example, multiple undersampling trajectories could be offset in k-space with respect to each other. For example, Cartesian trajectories may be used or spiral trajectories. The undersampling trajectories of the multiple MRI measurement datasets can have different sampling densities as a function of k-space position.

The varying undersampling trajectories may have varying sampling density (typically denser towards the center of k-space). A regular undersampling trajectory may be used, e.g., as used for conventional parallel imaging; or a segmented pattern with each segment having a regular undersampling with a possible shift.

MRI measurement datasets associated with different slices is acquired for one excitation. This corresponds to a multi-slice acquisition. This is of interest when the contrast varies slow enough such that multiple-slices may be acquired (e.g. for inversion based T₁-mapping when the target T₁ is relatively large).

It is also possible that, for the multiple k-space positions, the image resolution (defined as the maximal k-space coverage) varies. This is of particular interest when the contrast varies slower for a certain regime, allowing for the acquisitions of more k-space samples. It can also be of interest when the signal-to-noise ratio changes over the acquisition.

It is also possible that the sampling density (defined as the number of samples for the given k-space coverage) varies from MRI measurement dataset to MRI measurement dataset. This is of particular interest when the contrast varies slower for a certain regime, allowing for the acquisitions of more k-space samples. It can also be of interest when the signal-to-noise ratio changes over the acquisition.

A first k-space undersampling trajectory can sample a center of k-space at a first density and a second k-space undersampling trajectory can sample the center of k-space at the second density that is different from the first density. For example, it would be possible that the first density undersamples the center of k-space in the second density fully samples the center of k-space. Thereby, coil sensitivity maps can be calculated based on the fully sampled center of k-space available for the respective MRI measurement dataset; while the acquisition is not extended for the other MRI measurement datasets.

Next, at box 3020, an iterative optimization is performed to obtain a sequence of reconstructed 2-D or 3-D MRI image. This corresponds to MRI reconstruction.

At box 3030, the reconstructed MRI images output, e.g., to the user via a user interface. The reconstructed MRI image could also be stored.

Even though all MRI images of the sequence of MRI images associated with the sequence of MRI measurement datasets are calculated to enhance image quality through a joint reconstruction, less or even only one MRI image may be delivered to the user. In that case, the joint reconstruction of all contrasts is only performed to increase image quality. Thus, only a subset of all available MRI images can be selected for presentation to the user.

Details with respect to the iterative optimization of box 3020 are described below in connection with FIG. 4.

FIG. 4 illustrates multiple iterations 3071. Each iteration 3071 includes a regularization operation, box 3050; and a data-consistency operation at box 3060.

A concrete implementation of box 3050 and box 3060 could be based on Knoll, Florian, et al. “Deep learning methods for parallel magnetic resonance image reconstruction.” arXiv preprint arXiv:1904.01112 (2019): equation 12. Here, the left term included in the bracket corresponds to the regularization operation and the right term included in the bracket corresponds to the data-consistency operation. In this publication, motion artifacts are not compensated.

Then, at box 3070, it is checked whether a further iteration is required; and, in the affirmative, box 3050 and box 3060 are re-executed.

It would be possible that at box 3070 it is checked whether a certain predefined count of iterations has been reached. This can be an abort criterion. Other abort criteria are conceivable, e.g., as defined by the optimization method (convergence into a minimum), e.g., gradient descent.

FIG. 5 schematically illustrates aspects with respect to an MRI image 270. FIG. 5 schematically illustrates the MRI image 270. For instance, the MRI image 270 may be obtained in a certain iteration 3071.

According to various examples, for each iteration 3071, multiple such MRI images 270 may be obtained, e.g., for different contrasts and possibly for multiple motion states and points in time. For illustration, in a single shot acquisition, the multiple MRI images 270 may pertain to the same motion state and not provide time resolution. Differently, where a few or multiple acquisitions are used, the multiple MRI images 270 may pertain to different motion states at multiple points in time.

It is possible to concatenate such multiple MRI images 270 and then input the concatenation of MRI images 270 to the regularization operation. Thereby, a joint regularization is performed. Thereby, information can be shared between the concatenated MRI images. This can help to increase accuracy.

It would be possible that an input to the regularization operation includes an indicator indicative of a respective one of multiple excitation pulses, in case multiple excitation pulses are used. For example, an index may be incremented from excitation pulse to excitation pulse and the respective index may be input to the regularization operation. Similar considerations may also be applicable to multiple refocusing pulses. More generally, the input to the regularization operation can include an indicator indicative of the time offset with respect to the respective excitation files and/or with respect to the respective refocusing pulse.

This is based on the finding that in case of multiple excitation pulses, the separate excitations art treated as individual contrasts that are still jointly reconstructed. This is of relevance for motion or artifact prone acquisitions by the MRI images change from excitation pulse to excitation pulse, but a joint reconstruction still offers improvement of image quality. An example would be a multi-excitation HASTE sequence, see Table 1, example I. By providing the indicator indicative of a respective one of the multiple excitation pulses to the regularization operation, the regularization operation can be trained to compensate for motion artifacts between the MRI images. See Table 2, example II.

Alternatively or additionally, it would be possible that an input to the regularization operation includes an indicator indicative of a motion state of the movement of the patient associated with each one of the MRI measurement datasets of the sequence of MRI measurement datasets.

More generally, for the case of multiple excitation acquisitions, it is possible to include an additional components in the trainable regularization operation that help to align MRI images with same contrast but different excitation. This allows the algorithm to better align contrasts. For example, additional data indicative of the motion state such as respiratory signal or ECG may be acquired. This may be used to determine suitable training data (e.g. only combine data with same physiological state). It may also be used to determine realistic augmentation schemes. Finally, it can be also insert into the trainable algorithm so that it learns to address these physiological changes.

Alternatively or additionally, parameters related to MRI sequence or protocol such as echo time TE (or, more generally, time offset to an RF pulse), repetition time TR and/or flip angle FA may also be provided to the regularization operation such that it better adapts to different protocol settings.

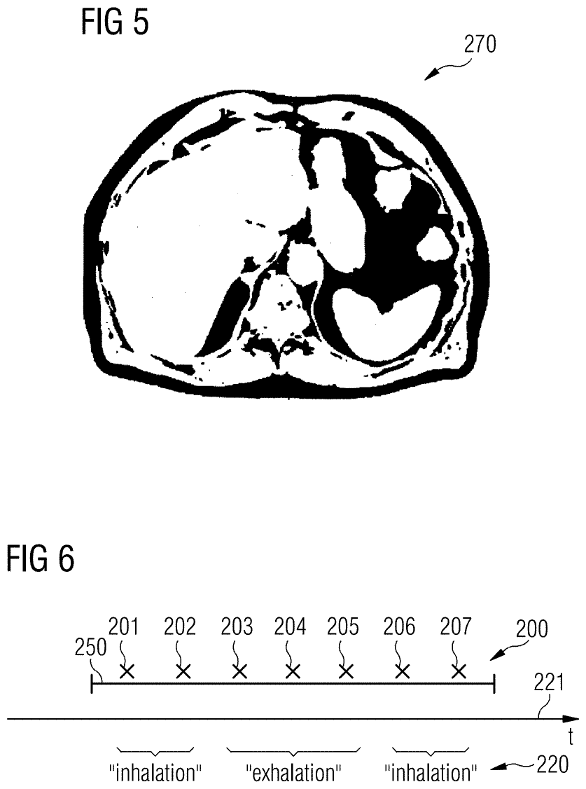

It is possible, but not mandatory, that the measurement time duration required to acquire multiple MRI measurement datasets is so long that multiple motion states of the movement of the patient are encountered. Such a scenario is illustrated in FIG. 6.

FIG. 6 illustrates a measurement time duration 250 extending in time domain 221. A sequence 200 of MRI images 201-207 (and corresponding MRI measurement datasets) is obtained at different points in time 221 within the measurement time duration 250. Also, the multiple MRI images 201-207 are associated with different motion states 220, as illustrated herein with respect to a movement induced by a breathing of the patient.

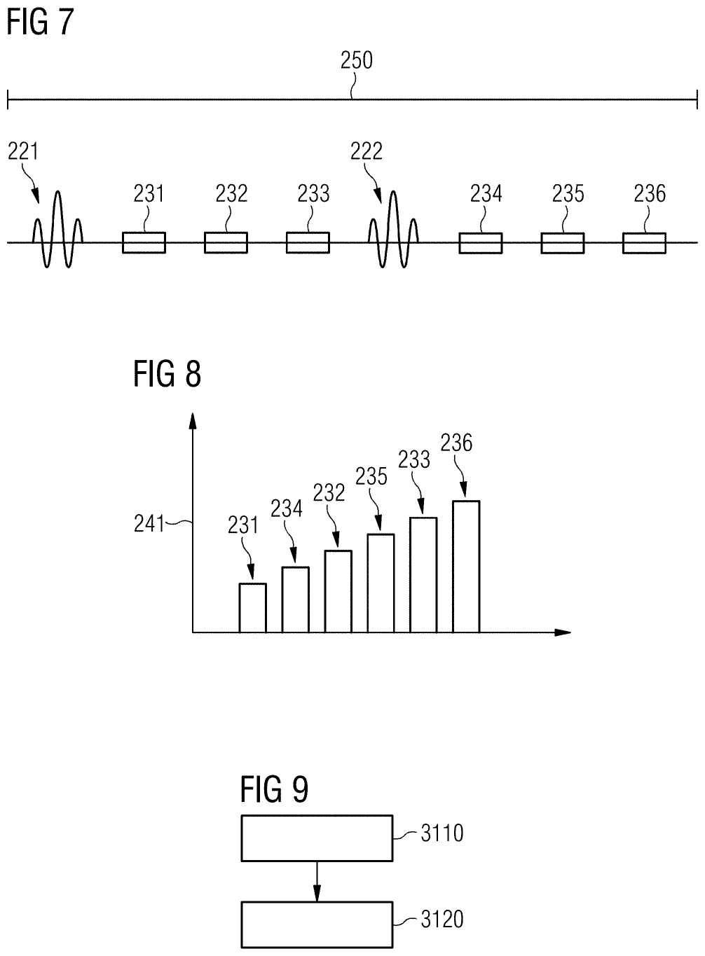

Another example is illustrated in FIG. 7. Here, multiple MRI measurement datasets 231-233 and 234-236 are acquired per RF pulse 221, 222 (e.g., excitation pulses or refocusing pulses). A total of two RF pulses 221-222 is used to acquire all MRI measurement datasets 231-236. Accordingly, the overall length of the measurement time duration 250 is comparably short. Thus, motion artifacts are unlikely to occur. For example, the measurement time duration 250 can be completed within a breath-hold of the patient. It would be possible that each of the multiple MRI measurement datasets 231-236 samples the entire k-space, at a comparably high acceleration factor.

As illustrated in FIG. 7, a sequence of MRI measurement datasets is acquired and the sequence of MRI measurement datasets could be generally associated with multiple spin echoes or multiple gradient echoes. It would even be possible that multiple gradient echoes are acquired per spin echo, i.e., implementing an interleaved acquisition. A corresponding sequence is, e.g., described in Feinberg, David A., and Koichi Oshio. “GRASE (gradient- and spin-echo) MR imaging: a new fast clinical imaging technique.” Radiology 181.2 (1991): 597-602.

FIG. 8 illustrates the time offsets 241 associated with the exposition of each one of the MRI measurement datasets 231-236 of FIG. 7. The time offsets 241 for the MRI measurement datasets 231-233 are determined with respect to the RF pulse 221; while the time offsets 241 for the MRI measurement datasets 234-236 are determined with respect to the subsequent RF pulse 222. These of the respective RF pulses 221-222 influencing the signal at the respective MRI measurement data sets 231-236.

FIG. 9 is a flowchart of a method according to various examples. FIG. 9 illustrates that at box 3120 inference is implemented, i.e., MRI images are reconstructed from MRI measurement datasets without a ground truth of the reconstructed MRI images being available. This is based on techniques as described above, e.g., in connection with FIG. 3. The MRI image reconstruction relies on a convolutional deep neural network. Machine learning can be implemented to train the convolutional deep neural network. This machine learning takes place in the training phase at box 3110. Weights of an unrolled network can be trained.

The training at the training phase at box 3110 can include a further iterative optimization, i.e., different to the iterative optimization described in connection with FIG. 4. The purpose of the iterative optimization of box 3110 is determining weights of the convolutional neural network. For this, a loss function can be considered for each iteration. The loss function is based on a difference between an output of the convolutional neural network at that iteration and a MRI image that has been predefined as ground truth. This means that the loss function can take smaller values if the difference is smaller; then, the convolutional network approximates the synthesized MRI image accurately, e.g., without aliasing artefacts. Depending on the value of the loss function, it is then possible to adjust weights of the convolutional neural network. This can be based on techniques such as back propagation.

The ground truth can be obtained from MRI measurement data sets that are based on a fully sampled k-space. The training strategy may be supervised, i.e. ground truth data are obtained by longer acquisitions e.g. using averaging and curated by human inspection.

Thereby, the trainable algorithm is expected to learn evolution of the contrasts in the sequence of MRI images and incorporates components that enforce the expected contrast evolution. This also goes by the name of joint reconstruction.

This convolutional network that has been appropriately trained can then be used to implement the regularization operation at box 3050 of FIG. 4.

Although the disclosure has been shown and described with respect to certain preferred embodiments, equivalents and modifications will occur to others skilled in the art upon the reading and understanding of the specification. The present disclosure includes all such equivalents and modifications and is limited only by the scope of the appended claims.

For illustration, above scenarios have been discussed in which the MRI reconstruction is implemented using a DL algorithm, in particular for the regularization operation. According to various techniques, it would be possible to combine such scenarios with non-DL implementations of the regularization operation. For example, a two-step approach may be implemented. Initially, a non-DL reconstruction, e.g., using compressed sensing, may be implemented to determine the sequence of MRI images. The non-DL MRI reconstruction may optionally include terms that enforce a similarity between multiple MRI images of the sequence of MRI images. Then, a technique as described above can be employed using a regularization operation implemented by a DL algorithm, e.g., a deep neural network. Here, multiple MRI images obtained from the 1^{st} step can be jointly passed through the DL algorithm

What is claimed is:

1. A computer-implemented method of reconstructing a sequence of magnetic resonance imaging (MRI) images, comprising:
obtaining, via one or more processors, a sequence of MRI measurement datasets, MRI measurement datasets of the sequence of MRI measurement datasets each being acquired (i) using at least one undersampling trajectory in k-space and a receiver coil array, and (ii) at multiple time offsets with respect to at least one excitation pulse and/or at least one refocusing pulse; and
performing, via one or more processors based on the MRI measurement datasets, an iterative process to obtain a sequence of reconstructed MRI images,
wherein the iterative process comprises, for each iteration of multiple iterations, a regularization operation and a data-consistency operation to obtain a sequence of current MRI images, the current MRI images of the sequence of current MRI images being associated with different time offsets of the multiple time offsets,
wherein the data-consistency operation is based on differences between the MRI measurement datasets and synthesized MRI measurement datasets, the synthesized MRI measurement datasets being based on a k-space representation of a prior image of the multiple iterations, the at least one undersampling trajectory, and a sensitivity map associated with the receiver coil array, and
wherein an input to the regularization operation comprises, for each iteration of the multiple iterations, a concatenation of multiple prior images obtained from a previous iteration of the multiple iterations, the multiple prior images being associated with the multiple time offsets.

2. The method of claim 1, wherein the at least one excitation pulse comprises a number of multiple excitation pulses less than six.

3. The method of claim 1, wherein the at least one excitation pulse comprises multiple excitation pulses, and
wherein the input to the regularization operation comprises an indicator indicative of a respective one of the multiple excitation pulses.

4. The method of claim 1, wherein the input to the regularization operation comprises an indicator indicative of a motion state of a movement of a patient associated with each respective one of the MRI measurement datasets of the sequence of MRI measurement datasets.

5. The method of claim 1, wherein the input to the regularization operation comprises an indicator indicative of at least one of a quantity of the multiple time offsets, a spacing of the multiple time offsets, and/or a flip angle of the at least one excitation pulse.

6. The method of claim 1, wherein the at least one undersampling trajectory comprises multiple undersampling trajectories, and
wherein different MRI measurement datasets of the sequence of MRI measurement datasets are acquired using different undersampling trajectories of the multiple undersampling trajectories.

7. The method of claim 6, wherein the different undersampling trajectories have different sampling densities as a function of k-space-position.

8. The method of claim 1, wherein, for each one of the multiple time offsets, multiple MRI measurement datasets are acquired at different slice positions.

9. The method of claim 1, wherein a spatial resolution varies across the sequence of MRI measurement datasets.

10. The method of claim 1, wherein:
the at least one undersampling trajectory comprises multiple undersampling trajectories,
a first one of the multiple undersampling trajectories samples a center of k-space at a first density,
a second one of the multiple undersampling trajectories samples the center of k-space at a second density, and
the first density is different from the second density.

11. The method of claim 1, wherein the at least one undersampling trajectory comprises multiple undersampling trajectories, and
wherein a sampling density of the multiple undersampling trajectories varies across the sequence of MRI measurements datasets.

12. The method of claim 1, wherein the sequence of MRI measurement datasets is associated with multiple spin echoes.

13. The method of claim 12, wherein the sequence of MRI measurement datasets is associated with multiple gradient echoes per respective spin echo of the multiple spin echoes.

14. The method of claim 1, further comprising:
selecting, from the sequence of reconstructed MRI images, a subset of one or more MRI images for presentation to a user.

15. A non-transitory computer-readable storage medium having executable instructions stored thereon that, when executed by one or more processors of a magnetic resonance imaging (MRI) device, cause the MRI device to reconstruct a sequence of magnetic resonance imaging (MRI) images by:
obtaining a sequence of MRI measurement datasets, MRI measurement datasets of the sequence of MRI measurement datasets each being acquired (i) using at least one undersampling trajectory in k-space and a receiver coil array, and (ii) at multiple time offsets with respect to at least one excitation pulse and/or at least one refocusing pulse; and
performing, based on the MRI measurement datasets, an iterative process to obtain a sequence of reconstructed MRI images,
wherein the iterative process comprises, for each iteration of multiple iterations, a regularization operation and a data-consistency operation to obtain a sequence of current MRI images, the current MRI images of the sequence of current MRI images being associated with different time offsets of the multiple time offsets,
wherein the data-consistency operation is based on differences between the MRI measurement datasets and synthesized MRI measurement datasets, the synthesized MRI measurement datasets being based on a k-space representation of a prior image of the multiple iterations, the at least one undersampling trajectory, and a sensitivity map associated with the receiver coil array, and
wherein an input to the regularization operation comprises, for each iteration of the multiple iterations, a concatenation of multiple prior images obtained from a previous iteration of the multiple iterations, the multiple prior images being associated with the multiple time offsets.
